(19) United States
(12) Patent Application Publication
(10) Pub. No.: US 2026/0113844 A1
(43) Pub. Date: Apr. 23, 2026

(54) WIRING BOARD

(71) Applicant: SHINKO ELECTRIC INDUSTRIES CO., LTD., Nagano (JP)

(72) Inventors: Tomoaki MACHIDA, Nagano (JP); Shuhei MOMOSE, Nagano (JP)

(21) Appl. No.: 19/357,722

(22) Filed: Oct. 14, 2025

(30) Foreign Application Priority Data
Oct. 17, 2024 (JP) 2024-181787

(51) Int. Cl. H05K 1/11; H05K 1/03

(52) U.S. Cl. CPC H05K 1/115; H05K 1/0306; H05K 2201/096; H05K 2201/09827

(57) ABSTRACT

A wiring board includes a core including a first glass plate, the core having a first primary surface, a second primary surface opposite to the first primary surface, and a side surface continuous with the first primary surface and the second primary surface, the side surface having a plurality of grooves reaching the first primary surface and the second primary surface, a first build-up layer provided on the first primary surface, a second build-up layer provided on the second primary surface, a plurality of through-metal trench layers provided inside the plurality of grooves, respectively, a first metal layer provided on the first primary surface and connected to the plurality of through-metal trench layers, and a second metal layer provided on the second primary surface and connected to the plurality of through-metal trench layers.

### CROSS-REFERENCE TO RELATED APPLICATIONS

This application is based upon and claims priority to Japanese Patent Application No. 2024-181787, filed on Oct. 17, 2024, the entire contents of which are incorporated herein by reference.

### FIELD

Certain aspects of the embodiments discussed herein are related to wiring boards.

### BACKGROUND

A wiring board having a core formed of a glass plate is known.

Related art include Japanese Laid-Open Patent Publication No. 2020-066554, and U.S. Patent Application Publication No. 2011/0147059, for example.

When manufacturing the known wiring board, a build-up layer is formed on a large-sized core, and the core having the build-up layer is thereafter singulated into multiple pieces. Before the singulation, an insulating layer included in the build-up layer is subjected to internal stress in a compression direction parallel to a surface of the core due to various heat treatments that are performed. For this reason, when the singulation is performed, constraints on the insulating layer is released, allowing the insulating layer to spread parallel to the surface of the core. As a result, tensile stress acts on the core from the insulating layer, and a crack may occur in the glass plate used as the core.

### SUMMARY

Accordingly, it is an object in one aspect of the embodiments to provide a wiring board capable of reducing cracking of a glass plate included in a core.

According to one aspect of the embodiments, a wiring board includes a core including a first glass plate, the core having a first primary surface, a second primary surface opposite to the first primary surface, and a side surface continuous with the first primary surface and the second primary surface, the side surface having a plurality of grooves reaching the first primary surface and the second primary surface; a first build-up layer provided on the first primary surface; a second build-up layer provided on the second primary surface; a plurality of through-metal trench layers provided inside the plurality of grooves, respectively; a first metal layer provided on the first primary surface and connected to the plurality of through-metal trench layers; and a second metal layer provided on the second primary surface and connected to the plurality of through-metal trench layers.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a plan view illustrating an example of a wiring board according to a first embodiment;

FIG. 2 is a cross sectional view illustrating a wiring board according to the first embodiment;

FIG. 3 is a diagram illustrating examples of product regions and cutting regions of a large-sized wiring board used for manufacturing the wiring board according to the first embodiment;

FIG. 4 is a cross sectional view illustrating an example of the large-sized wiring board used for manufacturing the wiring board according to the first embodiment;

FIG. 5 is a diagram illustrating examples of through-metal trench layers and metal layers arranged inside the cutting region of the large-sized wiring board used for manufacturing the wiring board according to the first embodiment;

FIG. 6A, FIG. 6B, FIG. 6C, and FIG. 6D are cross sectional views (part 1) illustrating an example of a method for manufacturing the wiring board according to the first embodiment;

FIG. 7A, FIG. 7B, and FIG. 7C are cross sectional views (part 2) illustrating the example of the method for manufacturing the wiring board according to the first embodiment;

FIG. 8A, FIG. 8B, and FIG. 8C are cross sectional views (part 3) illustrating the example of the method for manufacturing the wiring board according to the first embodiment;

FIG. 9A and FIG. 9B are cross sectional views (part 4) illustrating the example of the method for manufacturing the wiring board according to the first embodiment;

FIG. 10 is a plan view illustrating an example of the wiring board according to a second embodiment;

FIG. 11 is a diagram illustrating examples of through-metal trench layers and metal layers arranged inside the cutting region of the large-sized wiring board used for manufacturing the wiring board according to the second embodiment;

FIG. 12 is a cross sectional view illustrating an example of the wiring board according to a third embodiment; and

FIG. 13 is a cross sectional view illustrating the large-sized wiring board used for manufacturing the wiring board according to the third embodiment.

### DESCRIPTION OF EMBODIMENTS

Hereinafter, embodiments will be described in detail with reference to the accompanying drawings. In the present specification and the drawings, constituent elements having substantially the same functional configuration are designated by the same reference numerals, and a redundant description thereof may be omitted.

### First Embodiment

A first embodiment will be described. The first embodiment relates to a wiring board.

### Configuration of Wiring Board According to First Embodiment

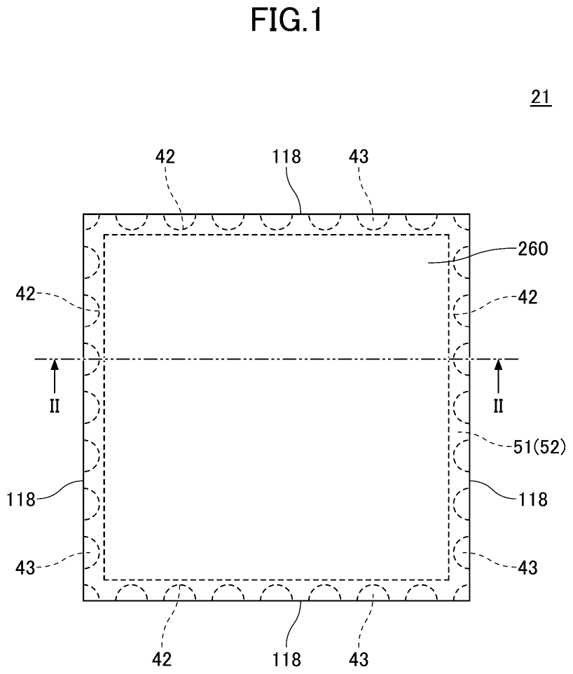

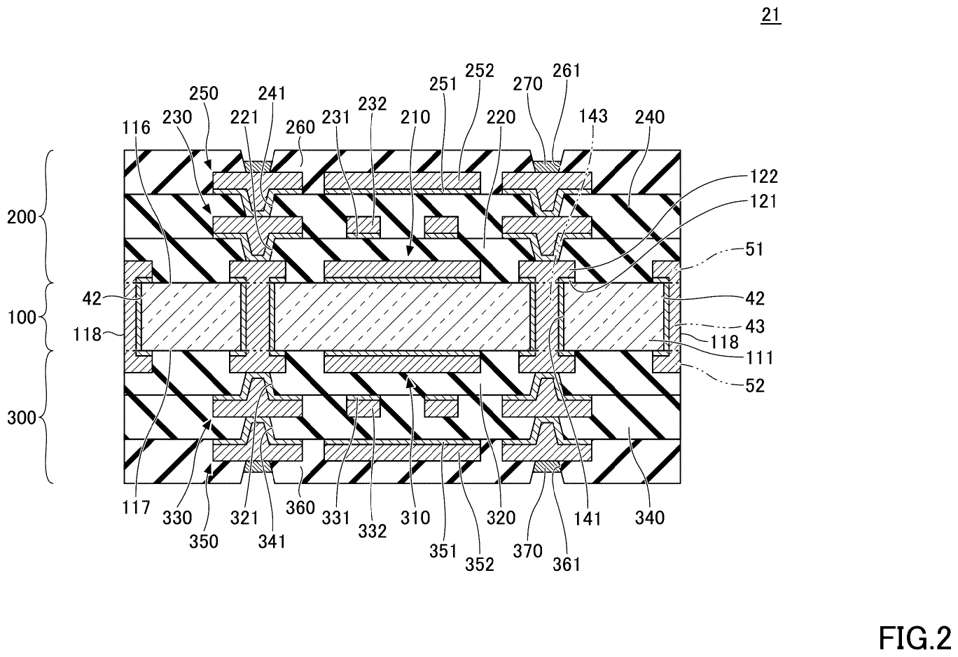

A configuration of a wiring board according to a first embodiment will be described. FIG. 1 is a plan view illustrating an example of a wiring board according to a first embodiment. FIG. 2 is a cross sectional view illustrating the example of the wiring board according to the first embodiment. FIG. 2 corresponds to a cross sectional view taken along a line II-II in FIG. 1.

As illustrated in FIG. 2, a wiring board 21 according to the first embodiment includes a core 100, a build-up layer 200, and a build-up layer 300. The core 100 has a first primary surface 116, and a second primary surface 117 opposite to the first primary surface 116. The build-up layer 200 is provided on the first primary surface 116 (one surface) of the core 100, and the build-up layer 300 is provided on the second primary surface 117 (the other surface) of the core 100. As illustrated in FIG. 1 and FIG. 2, the core 100 has a side surface 118 continuous with the first primary surface 116 and the second primary surface 117. The core 100 is formed of a glass plate 111. The glass plate 111 is an example of a first glass plate. The build-up layer 200 is an example of a first build-up layer, and the build-up layer 300 is an example of a second build-up layer.

In the present embodiment, for the sake of convenience, the side of the build-up layer 200 is referred to as an upper side or one side, and the side of the build-up layer 300 is referred to as a lower side or the other side, with reference to the core 100. In addition, a top surface of each constituent element is referred to as one surface or an upper surface, and a bottom surface of each constituent element is referred to as the other surface or a lower surface. However, the wiring board 21 may be used in an upside-down state or may be disposed at an arbitrary angle. Further, a plan view of an object refers to a view of the object in a normal direction to one surface of the core 100, and a planar shape of the object refers to a shape of the object in the plan view viewed in the normal direction to the one surface of the core 100.

A plurality of through holes 141 are formed in the core 100. For example, a diameter of the through hole 141 is approximately 100 μm. In addition, a plurality of grooves (or trenches) 42 reaching the first primary surface 116 and the second primary surface 117 are formed in the side surface 118. For example, the groove 42 has an arc-shaped planar shape with a radius of approximately 50 μm. The plurality of grooves 42 are arranged at a constant pitch, for example. The pitch of the grooves 42 is approximately 150 μm to approximately 200 μm, for example. The pitch of the grooves 42 is preferably greater than two times the radius of the grooves 42 and less than or equal to four times the radius of the grooves 42. Although the pitch and the radius of the grooves 42 do not need to be constant, the distance between centers of two adjacent grooves 42 is preferably greater than a sum of the radii of the two adjacent grooves 42 and less than or equal to two times the sum of the radii of the two adjacent grooves 42.

The wiring board 21 includes a plurality of through-metal trench layers (metal layers formed in trenches) 43 provided inside the plurality of grooves 42, respectively, and a plurality of through-metal trench layers 143 provided inside the plurality of through holes 141, respectively. That is, the plurality of through-metal trench layers 43 are provided at positions on an outer peripheral side of the core 100, while the plurality of through-metal trench layers 143 are provided at positions on an inner peripheral side of the core 100 than the plurality of through-metal trench layers 43. The wiring board 21 further includes a first metal layer 51, a second metal layer 52, an interconnect layer 210, and an interconnect layer 310. The first metal layer 51 is provided on the first primary surface 116, and is connected to the through-metal trench layers 43. The first metal layer 51 is in contact with the first primary surface 116. The second metal layer 52 is provided on the second primary surface 117, and is connected to the through-metal trench layers 43. The second metal layer 52 is in contact with the second primary surface 117. The first metal layer 51 and the second metal layer 52 are provided along the outer edge of the wiring board 21 in the plan view, and are connected to the plurality of through-metal trench layers 43. That is, the plurality of through-metal trench layers 43 are connected to one another through the first metal layer 51 and the second metal layer 52. The first metal layer 51 and the second metal layer 52 have a picture-frame-like planar shape in the plan view, respectively. The interconnect layer 210 is provided on the first primary surface 116. A portion of the interconnect layer 210 is connected to the through-metal trench layers 143. The interconnect layer 310 is provided on the second primary surface 117. A portion of the interconnect layer 310 is connected to the through-metal trench layers 143. Thicknesses of the first metal layer 51, the second metal layer 52, the interconnect layer 210, and the interconnect layer 310 are approximately 10 μm to approximately 30 μm, for example. In FIG. 1, the illustration of the through-metal trench layers 143, the interconnect layer 210, and the interconnect layer 310 is omitted for the sake of convenience.

For example, the through-metal trench layers 43, the through-metal trench layers 143, the first metal layer 51, the second metal layer 52, the interconnect layer 210, and the interconnect layer 310 include a seed layer 121 and a plating layer 122, respectively. The seed layer 121 is in contact with the glass plate 111, and the plating layer 122 is formed on one surface of the seed layer 121. A material used for the seed layer 121 and the plating layer 122 is copper (Cu) or the like. The seed layer 121 and the plating layer 122 may be continuous among the through-metal trench layers 43, the first metal layer 51, and the second metal layer 52. In addition, the seed layer 121 and the plating layer 122 may be continuous among the through-metal trench layers 143, a portion of the interconnect layer 210, and a portion of the interconnect layer 310.

The build-up layer 200 includes an interconnect layer 230 and an interconnect layer 250, an insulating layer 220 and an insulating layer 240, a solder resist layer 260, and a conductive layer 270. The build-up layer 300 includes an interconnect layer 330 and an interconnect layer 350, an insulating layer 320 and an insulating layer 340, a solder resist layer 360, and a conductive layer 370. The insulating layer 220 is provided between the interconnect layer 210 and the interconnect layer 230 that are adjacent to each other in a thickness direction, and the insulating layer 240 is provided between the interconnect layer 230 and the interconnect layer 250 that are adjacent to each other in the thickness direction. The insulating layer 320 is provided between the interconnect layer 310 and the interconnect layer 330 that are adjacent to each other in the thickness direction, and the insulating layer 340 is provided between the interconnect layer 330 and the interconnect layer 350 that are adjacent to each other in the thickness direction.

The insulating layer 220 is formed on the first primary surface 116 of the core 100 to cover the interconnect layer 210 and the first metal layer 51. A material used for the insulating layer 220 is an insulating resin including an epoxy-based resin, a polyimide-based resin, or the like as a main component, for example. A thickness of the insulating layer 220 is approximately 30 μm to approximately 40 μm, for example. The insulating layer 220 may include a filler, such as silica (SiO₂) or the like. A filler content in the insulating layer 220 can be appropriately set according to the required coefficient of thermal expansion (CTE).

Via holes 221 are formed in the insulating layer 220. The via holes 221 penetrate the insulating layer 220. The via holes 221 overlap the interconnect layer 210 in the plan view, and reach the interconnect layer 210.

The interconnect layer 230 is formed on one surface of the insulating layer 220. The interconnect layer 230 includes via conductors inside the via holes 221, and interconnect patterns on the one surface of the insulating layer 220. The interconnect patterns of the interconnect layer 230 are electrically connected to the interconnect layer 210 through the via conductors. The interconnect layer 230 includes a seed layer 231 and a plating layer 232, for example. The seed layer 231 is in contact with the insulating layer 220 and the plating layer 122, and the plating layer 232 is formed on one surface of the seed layer 231. For example, a material used for and a thickness of each of the seed layer 231 and the plating layer 232 are similar to those of the seed layer 121 and the plating layer 122, respectively.

The insulating layer 240 is formed on the one surface of the insulating layer 220 to cover the interconnect layer 230. For example, a material used for and a thickness of the insulating layer 240 are similar to those of the insulating layer 220, respectively. The insulating layer 240 may include a filler, such as silica (SiO₂) or the like. A filler content in the insulating layer 240 is similar to that of the insulating layer 220, for example.

Via holes 241 are formed in the insulating layer 240. The via holes 241 penetrate the insulating layer 240. The via holes 241 overlap the interconnect layer 230 in the plan view, and reach the interconnect layer 230.

The interconnect layer 250 is formed on one surface of the insulating layer 240. The interconnect layer 250 includes via conductors inside the via holes 241, and interconnect patterns on the one surface of the insulating layer 240. The interconnect patterns of the interconnect layer 250 are electrically connected to the interconnect layer 230 through the via conductors. The interconnect layer 250 includes a seed layer 251 and a plating layer 252, for example. The seed layer 251 is in contact with the insulating layer 240 and the plating layer 232, and the plating layer 252 is formed on one surface of the seed layer 251. For example, a material used for and a thickness of each of the seed layer 251 and the plating layer 252 are similar to those of the seed layer 121 and the plating layer 122, respectively.

The solder resist layer 260 is formed on the one surface of the insulating layer 240 to cover the interconnect layer 250. Openings 261 are formed in the solder resist layer 260. The openings 261 penetrate the solder resist layer 260. In the plan view, the openings 261 overlap electrode pads which are portions of the interconnect layer 250, and reach the electrode pads.

The conductive layer 270 is in contact with the interconnect layer 250 inside the openings 261, and covers the interconnect layer 250. The conductive layer 270 is a plating layer, for example. In FIG. 1, the illustration of the openings 261 and the conductive layer 270 are omitted for the sake of convenience.

The insulating layer 320 is formed on the second primary surface 117 of the core 100 to cover the interconnect layer 310 and the second metal layer 52. For example, a material used for and a thickness of the insulating layer 320 are similar to those of the insulating layer 220, respectively. The insulating layer 320 may include a filler, such as silica (SiO₂) or the like. A filler content in the insulating layer 320 is similar to that of the insulating layer 220, for example.

Via holes 321 are formed in the insulating layer 320. The via holes 321 penetrate the insulating layer 320. The via holes 321 overlap the interconnect layer 310 in the plan view, and reach the interconnect layer 310.

The interconnect layer 330 is formed on the other surface of the insulating layer 320. The interconnect layer 330 includes via conductors inside the via holes 321, and interconnect patterns on the other surface of the insulating layer 320. The interconnect patterns of the interconnect layer 330 are electrically connected to the interconnect layer 310 through the via conductors. The interconnect layer 330 includes a seed layer 331 and a plating layer 332, for example. The seed layer 331 is in contact with the insulating layer 320 and the plating layer 122, and the plating layer 332 is formed on the other surface of the seed layer 331. For example, a material used for and a thickness of each of the seed layer 331 and the plating layer 332 are similar to those of the seed layer 121 and the plating layer 122, respectively.

The insulating layer 340 is formed on the other surface of the insulating layer 320 to cover the interconnect layer 330. A material used for and a thickness of the insulating layer 340 are similar to those of the insulating layer 320, for example. The insulating layer 340 may include a filler, such as silica (SiO₂) or the like. A filler content in the insulating layer 340 is similar to that of the insulating layer 320, for example.

Via holes 341 are formed in the insulating layer 340. The via holes 341 penetrate the insulating layer 340. The via holes 341 overlap the interconnect layer 330 in the plan view, and reach the interconnect layer 330.

The interconnect layer 350 is formed on the other surface of the insulating layer 340. The interconnect layer 350 includes via conductors inside the via holes 341, and interconnect patterns on the other surface of the insulating layer 340. The interconnect patterns of the interconnect layer 350 are electrically connected to the interconnect layer 330 through the via conductors. The interconnect layer 350 includes a seed layer 351 and a plating layer 352, for example. The seed layer 351 is in contact with the insulating layer 340 and the plating layer 332, and the plating layer 352 is formed on the other surface of the seed layer 351. For example, a material used for and a thickness of the seed layer 351 and the plating layer 352 are similar to those of the seed layer 121 and the plating layer 122, respectively.

The solder resist layer 360 is formed on the other surface of the insulating layer 340 to cover the interconnect layer 350. Openings 361 are formed in the solder resist layer 360. The openings 361 penetrate the solder resist layer 360. In the plan view, the openings 361 overlap the electrode pads which are portions of the interconnect layer 350, and reach the electrode pads.

The conductive layer 370 is in contact with the interconnect layer 350 inside the openings 361, and covers the interconnect layer 350. The conductive layer 370 is a plating layer, for example. In FIG. 1, the illustration of the openings 361 and the conductive layer 370 is omitted for the sake of convenience.

### Method for Manufacturing Wiring Board According to First Embodiment

Next, a method for manufacturing the wiring board 21 according to the first embodiment will be described. The method for manufacturing the wiring board 21 includes a step (or process) of preparing a large-sized wiring board, and a step (or process) of singulating the large-sized wiring board.

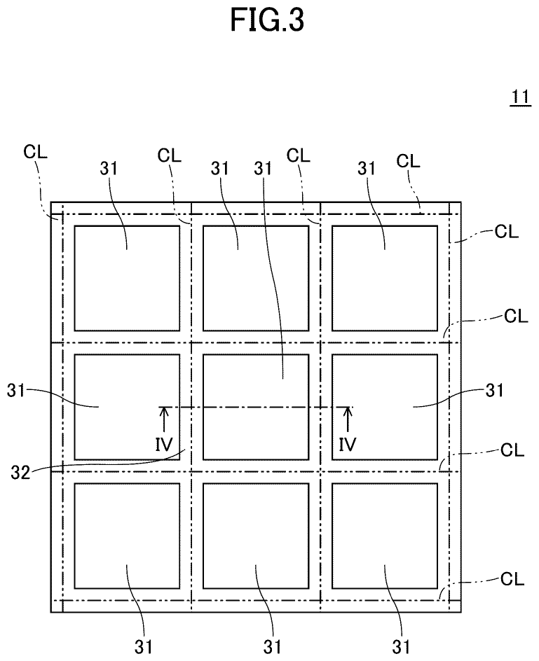

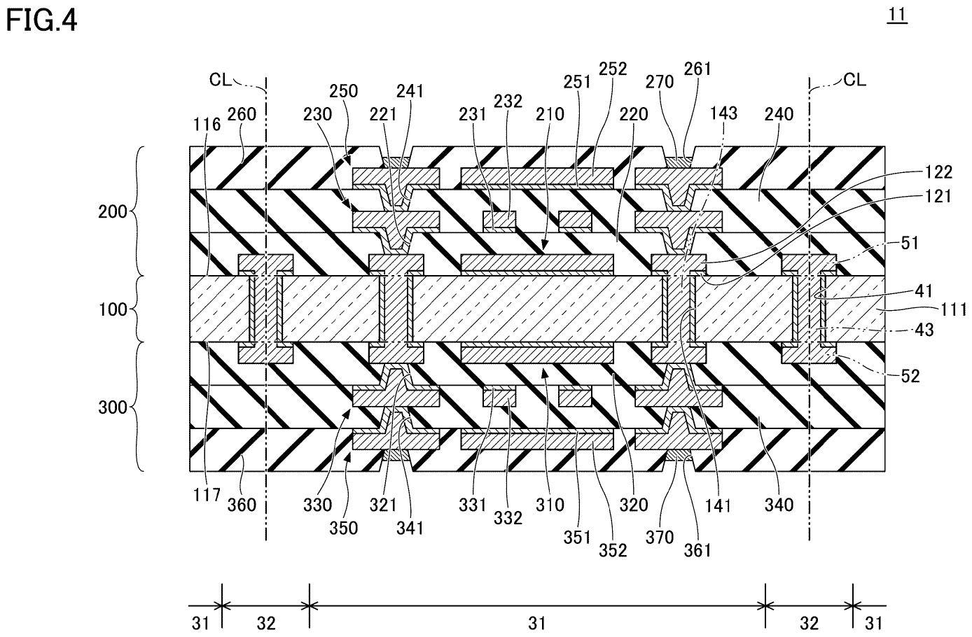

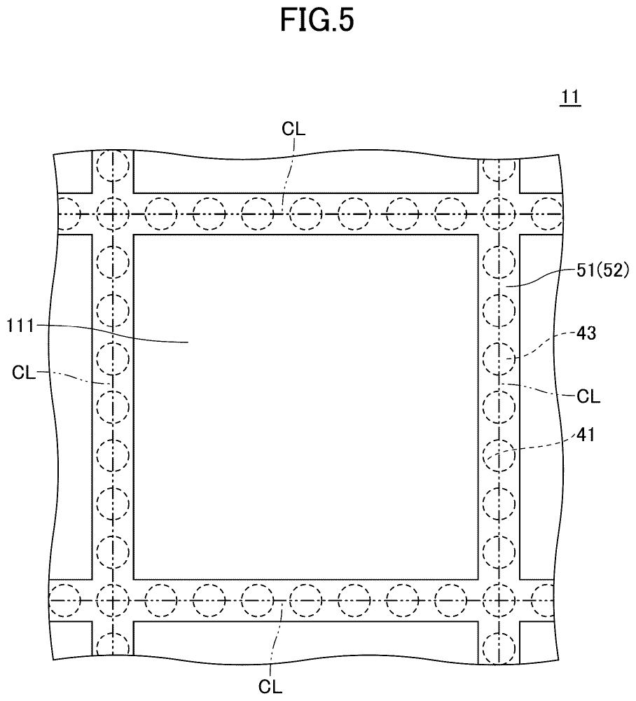

First, the large-sized wiring board will be described. FIG. 3 is a diagram illustrating product regions and cutting regions of the large-sized wiring board used for manufacturing the wiring board 21 according to the first embodiment. FIG. 4 is a cross sectional view illustrating the large-sized wiring board used for manufacturing the wiring board 21 according to the first embodiment. FIG. 5 is a diagram illustrating the through-metal trench layers and the metal layers in the cutting region of the large-sized wiring board used for manufacturing the wiring board 21 according to the first embodiment. FIG. 4 corresponds to a cross sectional view taken along a line IV-IV in FIG. 3.

As illustrated in FIG. 3, a large-sized wiring board 11 used for manufacturing the wiring board 21 according to the first embodiment includes a product region 31, and a cutting region 32 surrounding the product region 31 in the plan view. The wiring board 11 has nine product regions 31 arranged in a matrix of three rows and three columns in the plan view, and the cutting region 32 surrounds each of the product regions 31. The cutting region 32 includes cutting lines CL, and the wiring board 11 is cut along the cutting lines CL and singulated into nine wiring boards 21. Because the configuration of the product region 31 of the wiring board 11 is the same as the configuration of the wiring board 21, a description of the product region 31 will be omitted in the following description. For the sake of convenience, portions that ultimately become the corresponding constituent elements of the wiring board 21 are designated by the reference numerals of the final constituent elements, respectively.

As illustrated in FIG. 4 and FIG. 5, a plurality of through holes 41 are formed in the core 100 in the cutting region 32. For example, a diameter of the through hole 41 is approximately 100 μm. The diameter of the through hole 41 and the diameter of the through hole 141 may be identical or may be different from each other. For example, the diameter of the through hole 41 may be larger than the diameter of the through hole 141. The plurality of through holes 41 are arranged in the cutting region 32 at a constant pitch, for example. The pitch of the through holes 41 is approximately 150 μm to approximately 200 μm, for example. The pitch of the through holes 41 is preferably greater than the diameter of the through holes 41 and less than or equal to two times the diameter of the through holes 41. Although the pitch and the diameter of the through holes 41 do not need to be constant, a distance between centers of two adjacent through holes 41 is preferably greater than a sum of the radii of the two adjacent through holes 41 and less than or equal to two times the sum of the radii of the two through holes 41.

In the wiring board 11, the plurality of through-metal trench layers 43 are provided inside the plurality of through holes 41, respectively. The first metal layer 51 is provided on the first primary surface 116 in the cutting region 32, and is connected to the through-metal trench layers 43. The second metal layer 52 is provided on the second primary surface 117 in the cutting region 32, and is connected to the through-metal trench layers 43. The first metal layer 51 and the second metal layer 52 are provided over substantially the entire cutting region 32, and are connected to the plurality of through-metal trench layers 43. That is, the plurality of through-metal trench layers 43 are connected to one another through the first metal layer 51 and the second metal layer 52. The first metal layer 51 and the second metal layer 52 have a lattice-shaped planar shape.

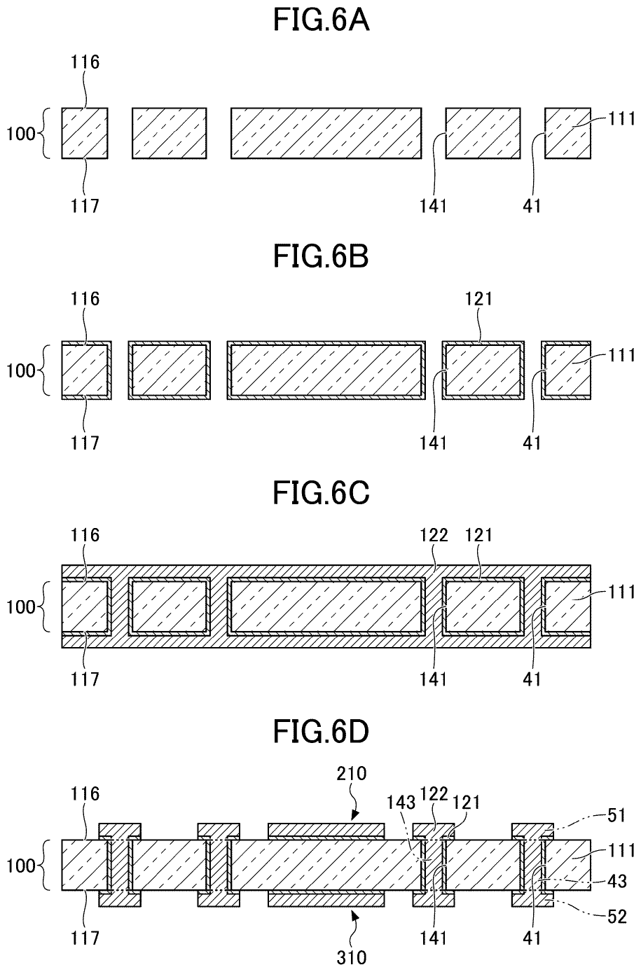

Next, the step (or process) of preparing a large-sized wiring board will be described. FIG. 6A through FIG. 9B are cross sectional views illustrating an example of the method for manufacturing the wiring board according to the first embodiment.

First, as illustrated in FIG. 6A, the core 100 is prepared. When preparing the core 100, the through holes 41 and the through holes 141 are formed in the glass plate 111.

Next, as illustrated in FIG. 6B, the seed layer 121 is formed on the entire surface of the glass plate 111. The seed layer 121 may be formed by electroless plating or sputtering, for example.

Thereafter, as illustrated in FIG. 6C, the plating layer 122 is formed on the one surface of the seed layer 121. The plating layer 122 may be formed by electrolytic plating using the seed layer 121 as a plating power supply path, for example.

Next, as illustrated in FIG. 6D, the first metal layer 51, the second metal layer 52, the interconnect layer 210, and the interconnect layer 310 are formed by etching a stacked body of the seed layer 121 and the plating layer 122 using a resist mask (not illustrated). The through-metal trench layers 43 are obtained in the through holes 41, and the through-metal trench layers 143 are obtained in the through holes 141. A material used for the resist mask is a dry film resist, for example.

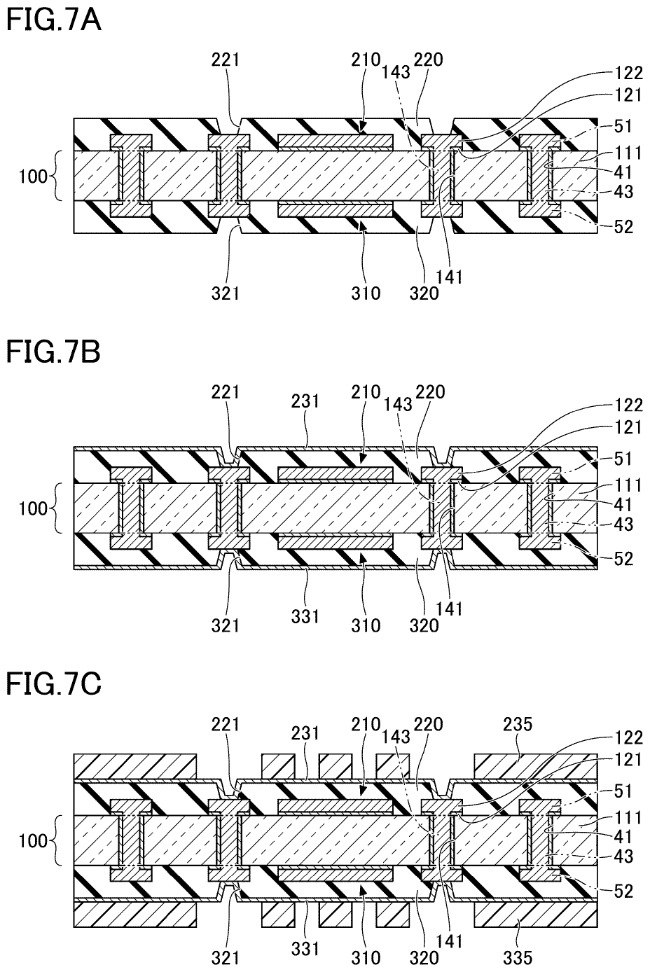

Next, as illustrated in FIG. 7A, the insulating layer 220 is formed on the first primary surface 116 of the core 100 to cover the interconnect layer 210 and the first metal layer 51, and the insulating layer 320 is formed on the second primary surface 117 of the core 100 to cover the interconnect layer 310 and the second metal layer 52. The insulating layer 220 and the insulating layer 320 can be formed by attaching an uncured resin film and curing the resin film by a heat treatment, for example. The insulating layer 220 and the insulating layer 320 may also be formed by coating a liquid resin and curing the liquid resin by a heat treatment.

Thereafter, the via holes 221 reaching the interconnect layer 210 are formed in the insulating layer 220, and the via holes 321 reaching the interconnect layer 310 are formed in the insulating layer 320. The via holes 221 and the via holes 321 can be formed by using a CO₂ laser, for example.

Subsequently, as illustrated in FIG. 7B, the seed layer 231 is formed to be in contact with the insulating layer 220 and the plating layer 122, and the seed layer 331 is formed to be in contact with the insulating layer 320 and the plating layer 122. The seed layer 231 and the seed layer 331 may be formed by electroless plating or sputtering, for example.

Next, as illustrated in FIG. 7C, a plating resist layer 235 having openings is formed on one surface of the seed layer 231, and a plating resist layer 335 having openings is formed on the other surface of the seed layer 331. The openings of the plating resist layer 235 are formed in portions where the interconnect layer 230 is to be formed. The openings of the plating resist layer 335 are formed in portions where the interconnect layer 330 is to be formed.

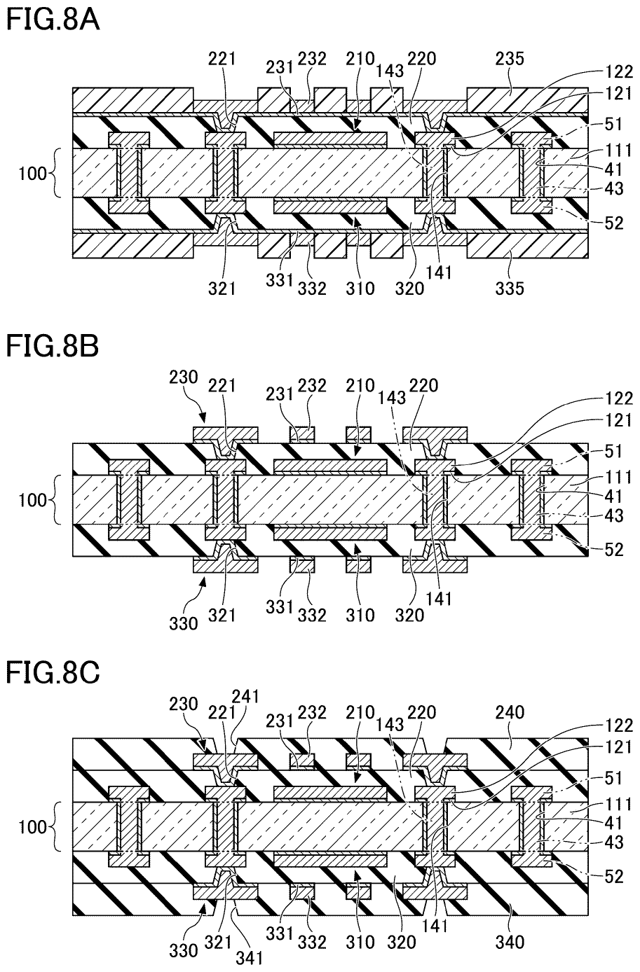

Thereafter, as illustrated in FIG. 8A, the plating layer 232 is formed inside the openings of the plating resist layer 235 by electrolytic plating using the seed layer 231 as a plating power supply path. Further, the plating layer 332 is formed inside the openings of the plating resist layer 335 by electrolytic plating using the seed layer 331 as a plating power supply path.

Next, as illustrated in FIG. 8B, the plating resist layer 235 and the plating resist layer 335 are removed. Next, portions of the seed layer 231 exposed from the plating layer 232 are removed, and portions of the seed layer 331 exposed from the plating layer 332 are removed. When removing the seed layer 231 and the seed layer 331, flash etching is performed, for example. The interconnect layer 230 and the interconnect layer 330 are formed in the manner described above.

Next, as illustrated in FIG. 8C, the insulating layer 240 is formed on one surface of the insulating layer 220 to cover the interconnect layer 230, and the insulating layer 340 is formed on the other surface of the insulating layer 320 to cover the interconnect layer 330. The insulating layer 320 and the insulating layer 340 can be formed by a method similar to that used to form the insulating layer 220 and the insulating layer 320.

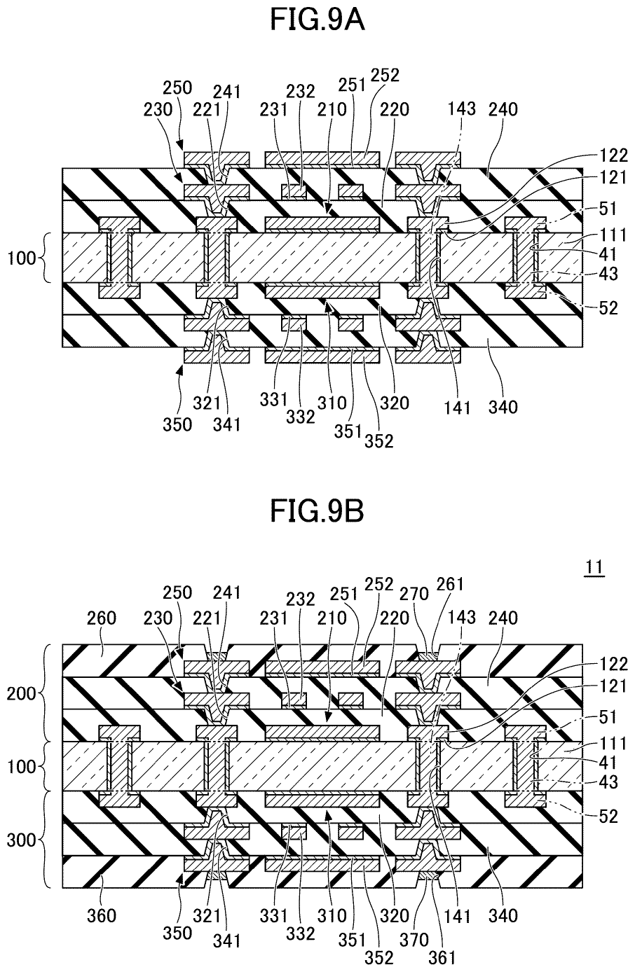

Thereafter, as illustrated in FIG. 9A, the interconnect layer 250 is formed on one surface of the insulating layer 240, and the interconnect layer 350 is formed on the other surface of the insulating layer 340. The interconnect layer 250 includes the seed layer 251 and the plating layer 252, and the interconnect layer 350 includes the seed layer 351 and the plating layer 352. The interconnect layer 250 can be formed by a method similar to that used to form the interconnect layer 230, and the interconnect layer 350 can be formed by a method similar to that used to form the interconnect layer 330.

Subsequently, as illustrated in FIG. 9B, the solder resist layer 260 is formed on one surface of the insulating layer 240, and the solder resist layer 360 is formed on the other surface of the insulating layer 340. Next, the openings 261 are formed in the solder resist layer 260, and the openings 361 are formed in the solder resist layer 360. Thereafter, the conductive layer 270 is formed inside the openings 261, and the conductive layer 370 is formed inside the openings 361.

The large-sized wiring board 11 can be manufactured and prepared in the manner described above.

In the step (or process) of singulating the large-sized wiring board 11, the wiring board 11 is cut along the cutting lines CL by a slicer or the like. Thus, nine wiring boards 21 according to the first embodiment are obtained. By cutting the large-sized wiring board 11 along the cutting lines CL, the plurality of through holes 41 are cut, thereby forming the plurality of grooves (or trenches) 42 of each of the nine wiring boards 21.

Hence, the wiring board 21 according to the first embodiment can be manufactured in the manner described above.

During the manufacture of the wiring board 21, when the large-sized wiring board 11 is singulated, internal stress of the insulating layer 220, the insulating layer 320, the insulating layer 240, and the insulating layer 340 is released, and tensile stress may act on the glass plate 111. In the present embodiment, even when such tensile stress acts on the glass plate 111, the through-metal trench layers 43, the first metal layer 51, and the second metal layer 52 relax the tensile stress acting on the glass plate 111. For this reason, it is possible to reduce cracks from occurring in the glass plate 111. In particular, because the first metal layer 51 and the second metal layer 52 are connected to the plurality of through-metal trench layers 43, and the plurality of through-metal trench layers 43 are connected to one another through the first metal layer 51 and the second metal layer 52, the tensile stress acting on the glass plate 111 can easily be relaxed.

The through-metal trench layers 43, the first metal layer 51, and the second metal layer 52 may be electrically insulated from the interconnect layer 210, the interconnect layer 230, the interconnect layer 250, the interconnect layer 310, the interconnect layer 330, and the interconnect layer 350 in the product region 31.

In the large-sized wiring board 11, the solder resist layer 260 and the solder resist layer 360 does not necessarily have to be formed in the cutting region 32. For example, the solder resist layer 360 may be removed from the cutting regions 32 when forming the openings 261, or the solder resist layer 260 may be removed from the cutting regions 32 when forming the openings 361. In addition, when singulating the large-sized wiring board 11, the solder resist layer 260 and the solder resist layer 360 in the cutting region 32 may be removed by laser ablation or the like before the cutting using the slicer or the like.

### Second Embodiment

A second embodiment will be described. The second embodiment differs from the first embodiment mainly in the configurations of the first metal layer and the second metal layer.

### Configuration of Wiring Board According to Second Embodiment

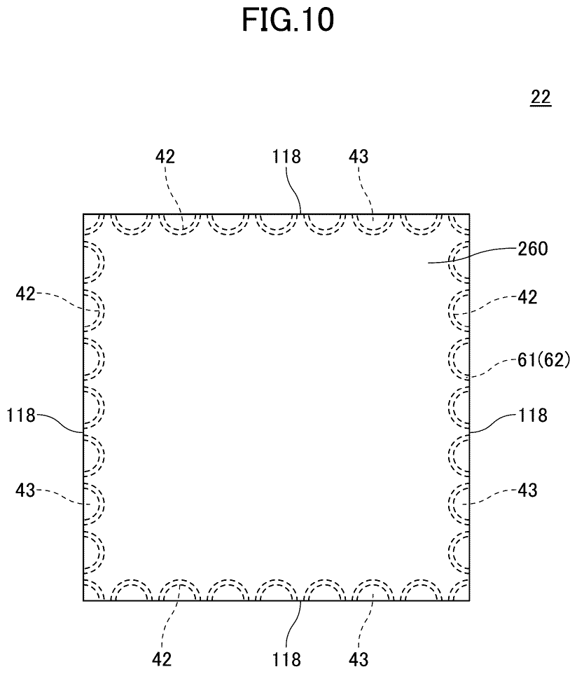

The configuration of the wiring board according to the second embodiment will be described. FIG. 10 is a plan view illustrating the wiring board according to the second embodiment.

As illustrated in FIG. 10, a wiring board 22 according to the second embodiment includes a plurality of first metal layers 61 in place of the first metal layer 51, and a plurality of second metal layers 62 in place of the second metal layer 52. The first metal layers 61 are provided on the first primary surface 116, and the second metal layers 62 are provided on the second primary surface 117. The first metal layers 61 are in contact with the first primary surface 116, and the second metal layers 62 are in contact with the second primary surface 117. The plurality of first metal layers 61 is connected to the plurality of through-metal trench layers 43, respectively, and the plurality of second metal layers 62 is connected to the plurality of through-metal trench layers 43, respectively. That is, one first metal layer 61 and one second metal layer 62 are connected to each metal layer 43 of the plurality of through-metal trench layers 43.

Otherwise, the configuration of the wiring board 22 is the same as that of the wiring board 21.

### Method for Manufacturing Wiring Board According to Second Embodiment

Next, the method for manufacturing the wiring board 22 according to the second embodiment will be described. The method for manufacturing the wiring board 22 includes a step (or process) of preparing a large-sized wiring board, and a step (or process) of singulating the large-sized wiring board.

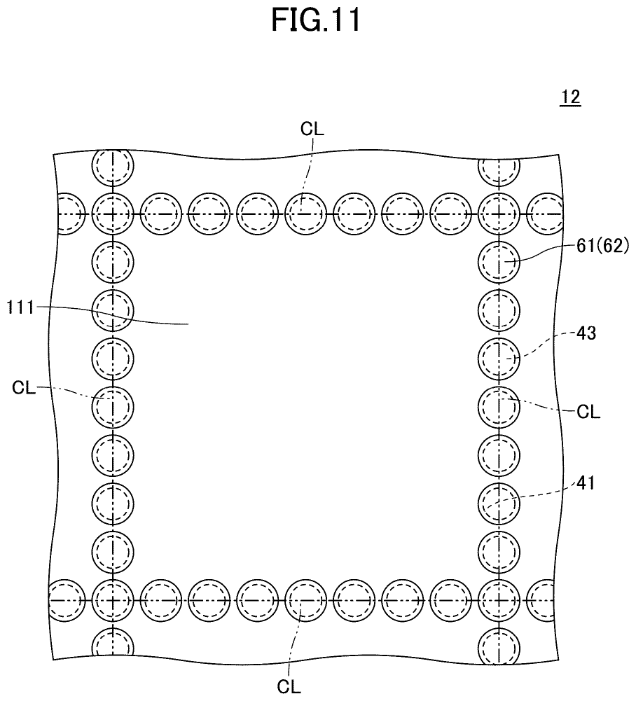

First, the large-sized wiring board will be described. FIG. 11 is a diagram illustrating the through-metal trench layers and the metal layers in the cutting regions of the large-sized wiring board used for manufacturing the wiring board 22 according to the second embodiment.

As illustrated in FIG. 11, in a large-sized wiring board 12 used for manufacturing the wiring board 22 according to the second embodiment, the plurality of through-metal trench layers 43 is provided in the plurality of through holes 41, respectively. The first metal layer 61 is provided on the first primary surface 116 in the cutting region 32, and the second metal layer 62 is provided on the second primary surface 117 in the cutting region 32. The plurality of first metal layers 61 is connected to the plurality of through-metal trench layers 43, respectively, and the plurality of second metal layers 62 is connected to the plurality of through-metal trench layers 43, respectively. That is, one first metal layer 61 and one second metal layer 62 are connected to each metal layer 43 of the plurality of through-metal trench layers 43.

Otherwise, the configuration of the wiring board 12 is the same as that of the wiring board 11.

In the step (or process) of singulating the large-sized wiring board 12, the wiring board 12 is cut along the cutting lines CL by the slicer or the like. Thus, nine wiring boards 22 according to the second embodiment are obtained.

The wiring board 22 according to the second embodiment can be manufactured in the manner described above.

During the manufacture of the wiring board 22, when the large-sized wiring board 12 is singulated, the internal stress of the insulating layer 220, the insulating layer 320, the insulating layer 240, and the insulating layer 340 is released, and tensile stress may act on the glass plate 111. In the present embodiment, even when such tensile stress acts on the glass plate 111, the through-metal trench layers 43, the first metal layer 61, and the second metal layer 62 relax the tensile stress acting on the glass plate 111. For this reason, it is possible to reduce cracks from occurring in the glass plate 111.

### Third Embodiment

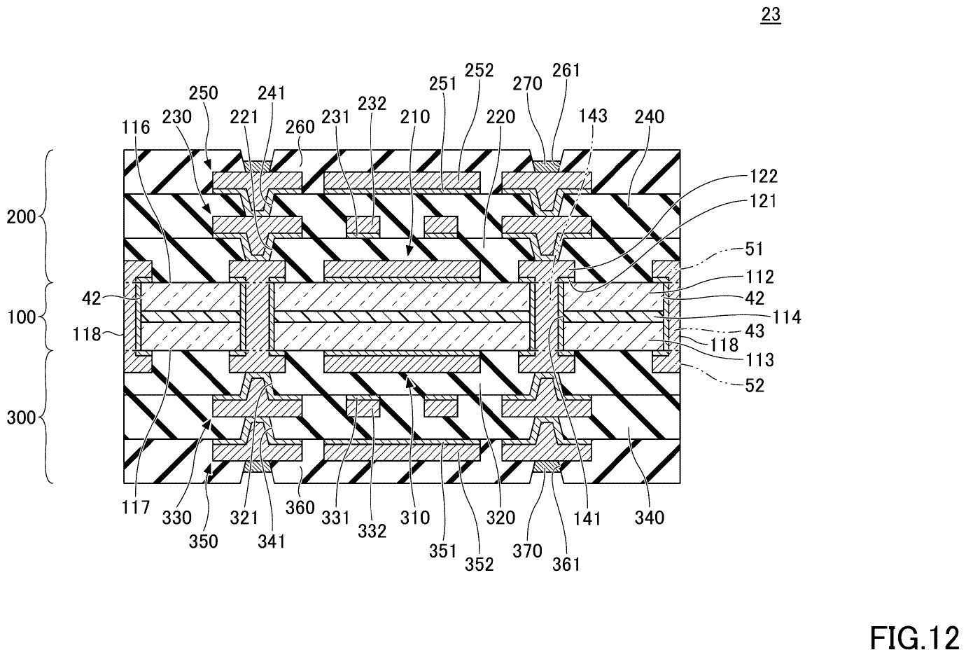

A third embodiment will be described. The third embodiment differs from the first embodiment mainly in the configuration of the core. FIG. 12 is a cross sectional view illustrating the wiring board according to the third embodiment.

As illustrated in FIG. 12, in a wiring board 23 according to the third embodiment, the core 100 includes a glass plate 112, an adhesive layer 114, and a glass plate 113, in place of the glass plate 111. The glass plate 112 has the first primary surface 116, and the glass plate 113 has the second primary surface 117. The adhesive layer 114 is provided between the glass plate 112 and the glass plate 113, and bonds the glass plate 112 and the glass plate 113. A material used for the adhesive layer 114 is an insulating resin including an epoxy-based resin, a polyimide-based resin, or the like as a main component, for example. A toughness of the adhesive layer 114 is higher than a toughness of the glass plate 112 and a toughness of the glass plate 113. The glass plate 112 is an example of a first glass plate, and the glass plate 113 is an example of a second glass plate.

Otherwise, the configuration of the wiring board 23 is the same as that of the wiring board 21.

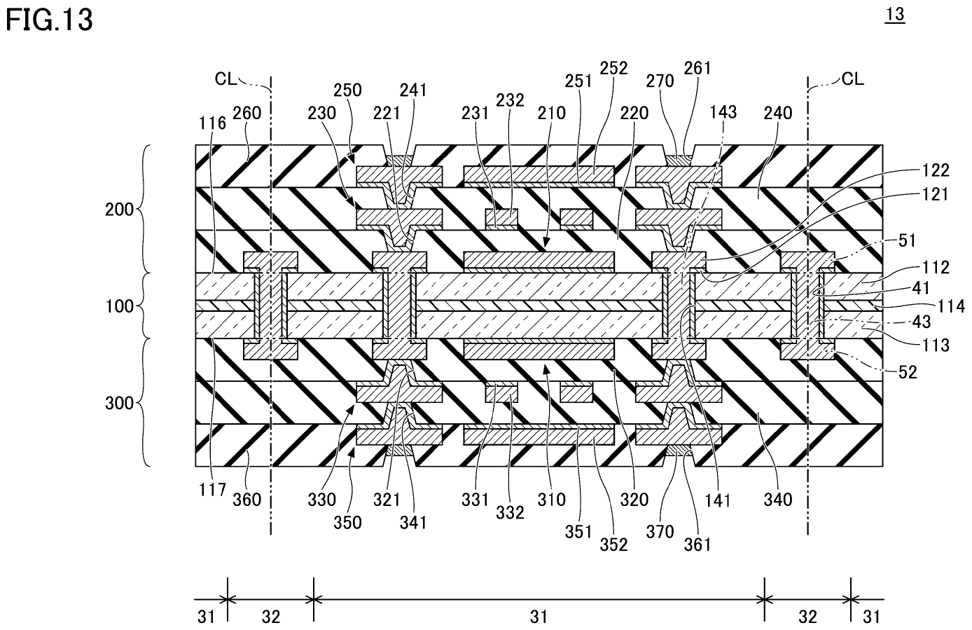

When forming the wiring board 23 according to the third embodiment, a large-sized wiring board 13 having a core including the glass plate 112, the glass plate 113, and the adhesive layer 114, in place of the glass plate 111, may be used in place of the core 100. FIG. 13 is a cross sectional view illustrating the large-sized wiring board 13 used for manufacturing the wiring board 23 according to the third embodiment.

During the manufacture of the wiring board 23, when the large-sized wiring board 13 is singulated, the internal stress of the insulating layer 220, the insulating layer 320, the insulating layer 240, and the insulating layer 340 is released, and tensile stress may act on the glass plate 112 and the glass plate 113. In the present embodiment, even when such tensile stress acts on the glass plate 112 and the glass plate 113, the through-metal trench layers 43, the first metal layer 51, and the second metal layer 52 relax the tensile stress acting on the glass plate 112 and the glass plate 113. For this reason, it is possible to reduce cracks from occurring in the glass plate 112 and the glass plate 113. In particular, because the first metal layer 51 and the second metal layer 52 are connected to the plurality of through-metal trench layers 43, and the plurality of through-metal trench layers 43 are connected to one another through the first metal layer 51 and the second metal layer 52, the tensile stress acting on the glass plate 112 and the glass plate 113 can easily be relaxed.

Further, because the core 100 has the adhesive layer 114, even when the through-metal trench layers 43 expand and contract in the thickness direction, the adhesive layer 114 can relax the thermal stress acting on the glass plate 112 and the glass plate 113.

In the third embodiment, similar to the second embodiment, the first metal layer 61 may be used in place of the first metal layer 51, and the second metal layer 62 may be used in place of the second metal layer 52.

According to the disclosed technique, it is possible to reduce cracking of the glass sheet included in the core.

Although the embodiments are numbered with, for example, “first,” “second,” or “third,” the ordinal numbers do not imply priorities of the embodiments. Many other variations and modifications will be apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A wiring board comprising:
a core including a first glass plate, the core having a first primary surface, a second primary surface opposite to the first primary surface, and a side surface continuous with the first primary surface and the second primary surface, the side surface having a plurality of grooves reaching the first primary surface and the second primary surface;
a first build-up layer provided on the first primary surface;
a second build-up layer provided on the second primary surface;
a plurality of through-metal trench layers provided inside the plurality of grooves, respectively;
a first metal layer provided on the first primary surface and connected to the plurality of through-metal trench layers; and
a second metal layer provided on the second primary surface and connected to the plurality of through-metal trench layers.

2. The wiring board as claimed in claim 1, wherein:
the first metal layer is connected to each through-metal trench layer of the plurality of through-metal trench layers, and
the second metal layer is connected to each through-metal trench layer of the plurality of the through-metal trench layers.

3. The wiring board as claimed in claim 2, wherein the first metal layer and the second metal layer have a picture-frame-like planar shape in a plan view, respectively.

4. The wiring board as claimed in claim 1, wherein the plurality of through-metal trench layers, the first metal layer, and the second metal layer include a seed layer in contact with the core, and a plating layer formed on the seed layer, respectively.

5. The wiring board as claimed in claim 1, wherein:
each first metal layer of a plurality of first metal layers is connected to one through-metal trench layer of the plurality of through-metal trench layers, and
each second metal layer of a plurality of second metal layers is connected to one through-metal trench layer of the plurality of through-metal trench layers.

6. The wiring board as claimed in claim 1, wherein:
the first glass plate has the first primary surface, and
the core includes:
a second glass plate having the second primary surface; and
an adhesive layer provided between the first glass plate and the second glass plate and bonding the first glass plate and the second glass plate.

7. The wiring board as claimed in claim 1, wherein the plurality of through-metal trench layers, the first metal layer, and the second metal layer are electrically insulated from the first build-up layer and the second build-up layer.

8. The wiring board as claimed in claim 7, wherein:
the plurality of through-metal trench layers include a plurality of first through-metal trench layers provided at positions on an outer peripheral side of the core, and a plurality of second through-metal trench layers provided at positions on an inner peripheral side of the core than the plurality of first through-metal trench layers, and
the plurality of second through-metal trench layers is electrically connected to the first build-up layer or the second build-up layer.

9. A wiring board comprising:
a core including a first glass plate, the core having a first primary surface and a second primary surface opposite to the first primary surface;
a first build-up layer provided on the first primary surface;
a second build-up layer provided on the second primary surface;
a product region, and a cutting region surrounding the product region in a plan view;
a plurality of through holes reaching the first primary surface and the second primary surface of the core and arranged inside the cutting region in the plan view;
a plurality of through-metal trench layers provided inside the plurality of through holes, respectively;
a first metal layer provided on the first primary surface, arranged inside the cutting region in the plan view, and connected to the plurality of through-metal trench layers; and
a second metal layer provided on the second primary surface, arranged inside the cutting region in the plan view, and connected to the plurality of through-metal trench layers.

10. The wiring board as claimed in claim 9, wherein:
the first metal layer is connected to each through-metal trench layer of the plurality of through-metal trench layers, and
the second metal layer is connected to each through-metal trench layer of the plurality of the through-metal trench layers.

11. The wiring board as claimed in claim 9, wherein:
each first metal layer of a plurality of first metal layers is connected to each through-metal trench layer of the plurality of through-metal trench layers, and
each second metal layer of a plurality of second metal layers is connected to each through-metal trench layer of the plurality of through-metal trench layers.

12. The wiring board as claimed in claim 9, wherein:
the first glass plate includes the first primary surface, and
the core includes:
a second glass plate having the second primary surface; and
an adhesive layer provided between the first glass plate and the second glass plate, and bonding the first glass plate and the second glass plate.

13. The wiring board as claimed in claim 9, wherein the plurality of through-metal trench layers, the first metal layer, and the second metal layer are electrically insulated from the first build-up layer and the second build-up layer.
